(19) United States
(12) Patent Application Publication
(10) Pub. No.: US 2007/0071884 A1
(43) Pub. Date: Mar. 29, 2007

(54) Electroluminescent element and a method of manufacturing the same

(76) Inventors: Koji Takeshita, Tokyo (JP); Takahisa Shimizu, Tokyo (JP); Hironori Kawakami, Tokyo (JP); Nahoko Kadota, Tokyo (JP)

Correspondence Address: SQUIRE, SANDERS & DEMPSEY L.L.P., 1 MARITIME PLAZA, SUITE 300, SAN FRANCISCO, CA, 94111, US

(21) Appl. No.: 11/510,074

(22) Filed: Aug. 24, 2006

(30) Foreign Application Priority Data
Sep. 27, 2005 (JP) 2005-279633
Feb. 22, 2006 (JP) 2006-044951

(51) Int. Cl. H01L 51/56

(52) U.S. Cl. 427/66; 313/504

(57) ABSTRACT

An organic luminescent layer of an organic electroluminescence element can be formed by relief printing using a plastic plate comprised a metal base material. A manufacturing method of an organic electroluminescent element including a substrate, a first electrode, an organic luminescent layer and a second electrode is provided, the method including forming an organic luminescent layer in upside of the first electrode by relief printing with the use of an organic luminescence ink, wherein the ink comprises an organic luminescent material dissolved in an organic solvent, and wherein a plastic plate having projection patterns comprising a resin on a metal base material is used in the relief printing.

### CROSS REFERENCE

This application claims priority to Japanese application numbers 2005-279633, filed on Sep. 27, 2005, and 2006-044951, filed on Feb. 22, 2006, which are incorporated by reference.

### BACKGROUND OF THE INVENTION

1. Field of the Invention

The present invention is related to an organic electroluminescent element and to a manufacturing method of the electroluminescent element, more particularly by means of printing method.

2. Description of the Related Art

An organic electroluminescent element has organic layers including an organic luminous layer between two opposed electrodes. It emits light by electric current to the organic luminous layer. Film thickness of the luminous layer is important, and it is necessary to make the film of thickness of around 100 nm to emit light efficiently. Even more particularly, it is necessary to form a thin luminous layer to make a display unit.

The organic luminescent material in the organic luminous layer can be made from low molecular materials and polymer materials. Generally a mask of a minute pattern is used, and the low molecular material is formed into a film by vaporization method using resistance heating. When a substrate for formation of thin film upsizes, in resistance heat coating by vaporization method, accuracy of the pattern becomes worse.

Thus polymer materials are applied to organic luminescent material. The coating liquid includes organic luminescent material dissolved in a solvent. Thin film formation by the wet coating method that uses this coating liquid has been tried. Wet coating method for the thin film formation can be performed by spin coat method, bar coat method, lobe coat method and dip coat method. But in those wet coating method, it is difficult to form a pattern with high accuracy. In addition, it is difficult to divide into three colors of RGB when RGB liquids are coated.

By a printing method, a divided pattern can be formed easily. So, it is thought that thin film formation by a printing method is more effective.

As for the organic electroluminescent element, it is often that a glass substrate is used as a substrate supporting electrodes. Therefore method to use hard metal printing plate like photogravure process is unsuitable. Offset printing method which utilizes a blanket made of rubber having an elasticity and relief printing method to use resins such as rubber having an elasticity or a photosensitive resin as printing plate are desirable.

As attempt by these printing methods, an approach (Japanese Patent Laid-Open No. 2001-93668 Official Gazette) by offset printing, and an approach (Japanese Patent Laid-Open No. 2001-155858 Official Gazette) by relief printing are proposed.

On the other hand, as for polymer materials, solubility in a solvent of water system and an alcohol system is poor. Especially, as for the macromolecular luminescent material, solubility in a solvent of water system and an alcohol system is poor. Therefore, it is necessary to dissolve polymer materials in organic solvent to make coating liquid (it is written down with “ink” as follows). Among organic solvent, a toluene, xylene and other aromatic organic solvent are preferred. Thus, ink including organic luminescent material (it is written down with “organic luminescence ink” as follows) is organic solvent type ink.

However, a rubber blanket used for offset printing is easy to swell due to an organic solvent such as toluene or xylene. In addition, it is easy to be transformed.

Offset printing is explained below. Ink is attached to a plate on which printing area is formed. The ink is transferred to an elastic blanket. Ink is further transferred to a substrate from a blanket. It is required that a blanket has elastic properties. Generally a rubber blanket is used. Kind of rubber is various from an olefinic system rubber to silicone system rubber. No rubber has resistance to a toluene, xylene and other solvents. Therefore, swelling and transformation of rubber are easy to occur. Therefore, rubber is inappropriate for printing of organic luminescence ink.

Thus, a plastic plate printing method to employ a water-developable photosensitive resin which is highly resistant to toluene, xylene and the other organic solvent which are a solvent of organic luminescence ink is a printing method most suitable for printing of organic luminescence ink.

A water-developable photosensitive plastic plate comprises photohardening light-sensitive resin material having the following characteristics: In uncured state, this material has high solubility to water. After hardening, this material does not dissolve in water.

Using the mask that light passes through only a region corresponding to a printing areas, a printing area is hardened by exposing a light-sensitive resin. Relief printing plate is formed by washing away a non-hardened zone with water.

Structure of a plate is the structure that a light-sensitive resin is laminated on a base material. A plastic sheet with flexible characteristics is generally used for base material because a plate is attached to a cylinder.

As explained above, printing with the use of a plastic plate comprising a water-developable light-sensitive resin suits for printing of an organic luminescence ink.

A main component of this light-sensitive resin is hydrophilic polymer, cross-linkable monomer and a photoinitiator.

In exposed portion, bridge formation of polymer and monomer progresses, and it hardens. It is thought that bridge formation of non-bridge formation portion progresses by natural light or indoor light to some extent after having finished exposure and developing. Therefore, the resin tends to shrink slowly with time. In addition, because a hydrophilic polymer is included, some dimensional change can occur by affect of environmental moisture, and dimensional change can occur by environmental temperature necessarily.

Structure of a photosensitive resin plate is the structure that a light-sensitive resin is laminated on base material. Dimension fluctuation of resin portion can be controlled by rigidity, hydrophobic property or thermal expansion coefficient of a base material to some extent. It is desirable that a printing plate can be attached easily to a printing cylinder. Therefore a flexible polyethylene terephthalate sheet is generally used as a base material. However, rigidity of a plastic base material such as polyethylene terephthalate is insufficient to completely control dimensional change of resin portion. In addition, dimensional change of a base material due to temperature change occurs as well.

The most suitable base material for resin plates having the following characteristic is chosen.

1. Dimensional change of a resin plate can be suppressed as much as possible.

2. The plate needs to be attachable to a printing cylinder as easily as possible.

An organic luminescent layer of an organic electroluminescence element can be formed by relief printing high minutely by using a plastic plate comprised the above mentioned base material.

The following problems when a luminescent layer was formed on a substrate by relief printing using an organic luminescence ink were examined.

A kind of the base material which could control dimension fluctuation of plastic plate was examined. In addition, it was examined whether dimensional accuracy required in electroluminescent element manufacturing was satisfied.

### SUMMARY OF THE INVENTION

An organic luminescent layer of an organic electroluminescence element can be formed by relief printing high minutely by using a plastic plate comprised a metal base material.

A manufacturing method of an organic electroluminescent element including a substrate, a first electrode, an organic luminescent layer and a second electrode,

the method including forming an organic luminescent layer in upside of the first electrode by relief printing with the use of an organic luminescence ink which an organic luminescent material is dissolved in an organic solvent,

wherein a plastic plate having projection pattern comprising resin on a metal base material is used in the relief printing.

### BRIEF DESCRIPTION OF DRAWINGS

FIG. 1 is a cross-sectional drawing of an organic electroluminescence element of an embodiment of the present invention.

FIG. 2 is a cross-sectional drawing of an example of a substrate of an active matrix method of an embodiment of the present invention.

FIGS. 3A and 3B are cross-sectional views of plastic plate used in an embodiment of the present invention.

FIGS. 4A, 4B, 4C and 4D are cross-sectional views of a manufacturing method of plastic plate.

FIG. 5 is a schematic diagram of a relief printing apparatus used in the present invention.

In these drawings, 1 is a substrate; 2 is a first electrode; 3 is a hole transport layer; 5 is a second electrode; 14a is organic luminescent ink; 20 is a substrate fixing stage; 24 is a substrate; 41 is a red (R) organic luminescent layer; 42 is a green (G) organic luminescent layer; 43 is a blue (B) organic luminescent layer; 7 is a partition wall; 102a is a non-hardened zone of a light-sensitive resin; 111 is a support medium; 112 is an active layer; 113 is a gate insulator; 114 is a gate electrode; 115 is an interlayer dielectric; 116 is a drain electrode; 117 is a planarizing layer; 118 is a contact hole; 119 is a data line; 120 is a thin film transistor; 201 is a metal base; 202 is a projection pattern comprising resin; 202a is a light-sensitive resin (non-hardening); 202b is a projection pattern comprising light-sensitive resin; 204 is a glass; 205 is a light shielding part; 206 is a photo mask; 207 is an active energy ray; 10 is an ink tank; 12 is an ink chamber; 14 is an anilox roll; 14a is ink; 16 is a relief printing plate; 18 is a printing cylinder; 20 is a stage; and 24 is a substrate.

### DESCRIPTION OF THE PREFERRED EMBODIMENTS

Detailed description of the preferred embodiment to make an organic electroluminescence element of a passive matrix method is explained.

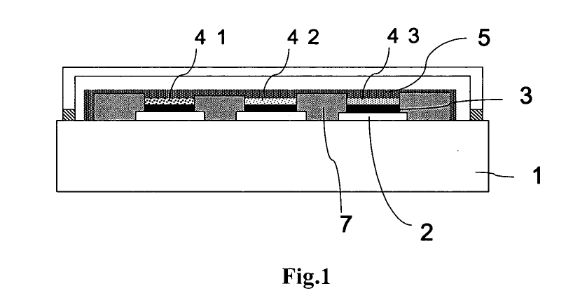

A sectional drawing of an organic electroluminescence element of an embodiment of the present invention is shown in FIG. 1.

For driving type of an organic electroluminescent element, passive matrix type and active matrix type are exemplified. An organic electroluminescent element of the present invention can be applied to both organic electroluminescent element of a passive matrix type and an organic electroluminescent element of an active matrix type.

An organic electroluminescent element of a passive matrix type is the organic electroluminescent element which includes stripe-shaped electrodes that are opposed to with perpendicular state. It emits light in the intersection point. On the other hand, an active matrix type has so-called thin film transistor (TFT) substrate. Transistor is formed with every pixel. In active matrix type, light is emitted by every pixel independently.

As shown in FIG. 1, an organic electroluminescence element of the present invention can have a first electrode 2 as an anode on a substrate 1 in the shape of a stripe. Partition walls 7 are formed between the first electrodes. It is desirable that partition walls 7 cover first electrode ends for the purpose of preventing a short circuit due to burr of a first electrode edge.

And an organic electroluminescence element of the present invention has an organic luminescent layer and a luminescence assist layer in a region sectioned by partition walls 7 on first electrodes 2.

As for the layer sandwiched between first electrodes 2 and second electrode 5, even an organic luminescent layer alone is preferable, and even a laminate of an organic luminescent layer and a luminescence assist layer is preferable.

As a luminescence assist layer, there is a hole transport layer, a hole injection layer, an electron transport layer and an electron injection layer.

The organic luminescence medium layer which is a laminate of a hole transport layer 3 that is a luminescence assist layer and organic luminescent layers (41, 42, 43) is shown in FIG. 1.

A hole transport layer 3 is formed on a first electrode 2.

Red (R) organic luminescent layer 41, green (G) organic luminescent layer 42 and blue (B) organic luminescent layer 43 are formed on a hole transport layer 3 respectively.

Next, as a cathode, second electrode 5 is placed on an organic luminescent layer to be facing with first electrode 2 which is anode.

In the case of a passive matrix method, second electrode is formed in the shape of stripe to be perpendicular to stripe first electrode. In the case of an active matrix method, second electrode is formed on a whole area of an organic electroluminescence element.

Further, sealing body such as glass cap which is not illustrated is stuck on a whole area of effective picture elements by adhesive to prevent infiltration of moisture and oxygen to a first electrode, an organic luminescence medium layer including an organic luminescent layer and a second electrode.

An organic electroluminescence element of the present invention comprises a substrate, pattern-formed first electrodes supported by the substrate, an organic luminescent layer and a second electrode.

An organic electroluminescence element of the present invention may be reverse structure shown in FIG. 1. In other words, a first electrode may be a cathode. A second electrode may be an anode.

Instead of sealing body such as glass caps, an organic electroluminescence element may contain a passivation layer, a protective layer or a layer having their two functions.

A passivation layer protects an organic luminescent layer, a luminescent assist layer and electrodes from infiltration of outside oxygen and moisture. A protective layer protects an organic luminescent layer, a luminescent assist layer and electrodes from exteranal stress.

A manufacturing method of an organic electroluminescence element of the present invention is explained.

A substrate having insulating property can be used as a substrate. In the case of an organic electroluminescent element of bottom emission method, it is necessary to use a clear substrate.

By way of example only, a glass substrate and a quartz substrate can be used. In addition, a plastic film and sheet such as polypropylene, polyether sulfone, polycarbonate, cyclo olefin polymers, polyarylate, polyamide, polymethyl methacrylate, poly ethylene terephthalate and polyethylenenaphthalate can be used. Metallic oxide thin film, metal fluoride thin film, metal nitride thin film, metal oxynitriding membrane thin film or macromolecule resin film may be formed on a plastic film or sheet to prevent moisture from entering an organic luminescent medium layer.

In addition, it is preferable for a substrate to be heated beforehand. Moisture adsorbed in internal and surface of a substrate is reduced by heating. In addition, depending on a material laminated on a substrate, surface of a substrate may be processed by processing such as ultrasonic cleaning processing, corona discharge treatment, plasma treatment and UV ozonization for improvement of adhesion.

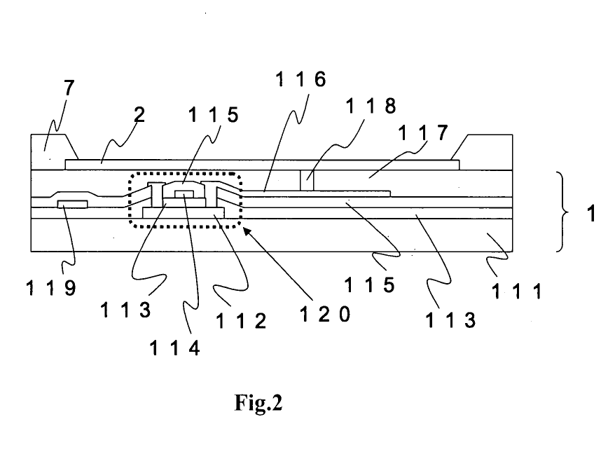

In addition, thin film transistor (TFT) is formed on a substrate, and a substrate for an organic electroluminescent element of active matrix method can be made. A cross-sectional figure of an example of a substrate of active matrix method of the present invention is shown in FIG. 2. On TFT 120, planarizing layer 117 is formed. A bottom electrode (the first electrode 2) of an organic electroluminescent element is formed on planarizing layer 117. Contact hole 118 is installed in planarizing layer 117. The bottom electrode is electrically connected to TFT by means of contact hole 118. Due to such a constitution, superior electrical insulating property can be achieved between TFT and an organic electroluminescent element. Insulating film between layers 115 is necessary. In FIG. 2, data line 119 is also illustrated.

TFT 120 and the upward organic electroluminescent element are supported with support medium 111. Support medium 111 should be superior in mechanical intensity and dimensional stability. Materials exemplified as material for a substrate can be used as material for support medium 111.

For thin film transistor 120 in a support medium, well-known thin film transistor can be used. Thin film transistor comprising the active layer that a source/drain region and a channel area are formed, the gate insulator and the gate electrode is exemplified. Configuration of thin film transistor is not limited especially. By way of example only, staggered type, reverse staggered type, top gate type and coplanar type can be used.

Active layer 112 can be formed by inorganic semiconductor material such as amorphia Si, polycrystalline silicon, crystallite Si, cadmium selenide or organic semiconductor material such as thiophene oligomer or poly (phenylene vinylene).

These active layers are made by the following methods:

1. A method to do ion doping after having laminated amorphous silicon by plasma CVD technique.

2. A method comprising the following process: Amorphous silicon is formed by LPCVD method using SiH₄ gas. By means of crystallization of amorphous silicon by solid phase epitaxy, a poly Si is obtained. Ion doping is done by ion implantation method.

3. A low temperature processing method comprising the following process:

Amorphous silicon is formed. By way of example only, Si₂H₆ gas is used, and amorphous silicon is formed by LPCVD method. Amorphous silicon is formed by PECVD method by means of SiH₄ gas. It is annealed by laser such as excimer lasers. A poly Si is obtained by crystallization of amorphous silicon. Ion doping is done by ion doping method.

4. A high temperature processing method comprising the following process: A poly Si is laminated by low pressure CVD method or LPCVD method. Thermal oxidation is done in more than 1,000 degrees Celsius, and gate insulator is formed. Thereupon, gate electrode 114 of an n+ poly Si is formed. Ion doping is done by ion implantation method.

For gate insulator 113, conventional gate insulator can be used. By way of example only, SiO₂ formed by PECVD method or LPCVD method and SiO₂ made by thermal oxidation of polysilicon film can be used.

For gate electrode 114, a conventional gate electrode can be used. By way of example only, metal such as aluminum, copper, refractory metal such as titanium, tantalum, tungsten, a poly Si, silicide of refractory metal and polycide can be used.

For configuration of thin film transistor 120, a single gate structure, a double gate structure, multiple gating configuration having gate electrodes of more than 3 are exemplified. In addition, LDD configuration, offset configuration may be provided. Even more particularly, thin film transistors of more than 2 may be placed all over one pixel.

It is necessary for a thin film transistor of a display unit of the present invention to function as a switching element so that drain electrode 116 of transistor is connected electrically with pixel electrodes (the first electrodes) of an organic electroluminescent element. In the case of top emission configuration, it is necessary for metal reflecting back light to be used as pixel electrodes.

Drain electrode 116 of thin film transistor 120 is connected with pixel electrodes (the first electrodes) of an organic electroluminescent element by a connection electric wiring. A connection electric wiring is formed in contact hole 118 penetrating through planarizing layer 117.

For a material of planarizing layer 117, inorganic materials such as SiO₂, spin-on-glass, SiN (Si₃N₄), TaO (Ta₂O₅) and organic materials such as polyimide resin, acrylic resin, photoresist material and black matrix material can be used. Spin coating, CVD and evaporation method can be selected depending on these materials. A photosensitive resin is used as a planarizing layer if necessary, and, by procedure of photolithography, contact hole 118 is formed. Or after having formed a planarizing layer on a whole area, contact hole 118 is formed by dry etching or wet etching in position corresponding to lower thin film transistor 120. Contact hole is buried by conductive material. And, the contact hole is connected with pixel electrodes on a planarizing layer. A planarizing layer should be able to cover up TFT, capacitor and electric wiring. Thickness of the planarizing layer should be several μm, and, by way of example only, it is about 3 μm.

The first electrode is formed on a substrate. When the first electrode is anode, the following material can be used: metal complex oxide such as ITO (indium tin complex oxide), IZO (indium zinc complex oxide), stannic oxide, zinc oxide, indium oxide and zinc aluminium complex oxide; metallic substances such as gold, platinum and chromium; and a layer stack comprising these materials.

A formation method of the first electrode is explained below.

Dry method such as resistance heating evaporation method, electron-beam evaporation technique, reactivity evaporation method, ion plating method and sputtering method can be used depending on the material.

In addition, ITO is preferable for reasons of the follows: low electrical resistance, high solvent resistance, and high translucency (in the case of bottom emission method).

ITO is formed on a glass substrate by sputter method. The first electrode is formed by patterning by photolithography method of ITO.

After having formed a first electrode, partition walls are formed to cover a first electrode edge. Partition walls have to have insulating property. By reason of the formation of partition walls, photosensitive materials can be used.

A positive type and negative type can be used as a photosensitive material. Light hardening resins such as photo radical polymerization system, photo cation cure corollary or copolymer containing acrylonitrile composition, poly vinylphenol, polyvinyl alcohol, novolac resin, polyimide resin and cyanoethyl pullulan can be used. In addition, as formation material of partition walls, SiO₂ and TiO₂ can be used.

When a formation material of partition walls is a photosensitive material, solution of a formation material can be entirely coated by slit coat method or spin coating method.

And patterning is performed by photolithography method including exposure process and development process. In the case of spin coating method, height of partition walls can be controlled under conditions of rotation number. However, only by one coating, height of partition walls is limited. If spin-coating process is repeated more than once, partition walls of height more than the limited height can be formed.

When partition walls are formed by photolithography method using a photosensitive material, configuration of partition walls is controllable by exposure condition and development condition. Example is described below.

A photosensitive resin of negative type is used. By exposure, development and post-bake, partition walls are formed. Configuration of a partition wall end is a taper configuration.

Development conditions such as a kind, density, temperature of a photographic developer or developing time should be controlled to form the partition walls.

When condition of development is mild, the following partition walls are formed: Configuration of a partition wall end is taper configuration.

On the contrary, when development condition is strong, the following partition walls are formed: Configuration of a partition wall end is inverse configuration of taper configuration.

In addition, when a formation material of partition walls is SiO₂ or TiO₂, partition walls can be formed by dry method such as sputtering method or chemical vapor deposition. For this case, patterning of partition walls can be performed by a mask or photolithography method.

An organic luminescent layer and a luminescence assist layer are formed next.

An organic luminous (luminescent) layer is the layer which emits light when electric current flows.

The following material can be used as an organic luminescent material of an organic luminous layer:

The following low molecular type luminescent material can be used:

9,10-diaryl anthracenes, pyrene, coronene, perylene, rubrene, 1,1,4,4-tetra phenylbutadiene, tris (8-hydroxyquinolonate) aluminium complex, tris (4-methyl-8-hydroxyquinolonate) aluminium complex, bis (8-hydroxyquinolonate) zinc complex, tris (4-methyl-5-trifluoromethyl-8-hydroxyquinolonate) aluminium complex, tris (4-methyl-5-cyano-8-hydroxyquinolonate) aluminium complex, bis (2-methyl-5-trifluoromethyl-8-quinolinolate) [4-(4-cyanophenyl) phenolate] aluminium complex, bis (2-methyl-5-cyano-8-quinolinolate) [4-(4-cyanophenyl) phenolate] aluminium complex, tris (8-quinolinolate) scandium complex, bis [8-(para-tosyl) aminoquinoline] zinc complex and cadmium complex, 1,2,3,4-tetraphenylcyclopentadiene and poly-2,5-diheptyloxi-paraphenylenevinylene.

In addition, the material which the following low molecular type luminescent material is scattered in a polymeric material can be used: coumarin corollary fluorescent substance, perylene corollary fluorescent substance, pyran type fluorescent substance, anthrone corollary fluorescent substance, porphyrin corollary fluorescent substance, quinacridon corollary fluorescent substance, N, N′-dialkyl displacement quinacridon corollary fluorescent substance, naphthalimido corollary fluorescent substance, N, N′-diaryl displacement pyrrolo pyrrole series fluorescent substance and phosphorescence fluor such as Ir chelate. Polystyrene, polymethyl methacrylate and polyvinylcarbazole can be used as a polymeric material.

In addition, the following macromolecule luminescent materials can be used: poly (2-decyloxy-1,4-phenylene) (DO-PPP), poly [2,5-bis-[2-(N, N, N-triethylammonium) ethoxy]-1,4-phenyl-alt-1,4-phenylene] a dibromide (PPP-NEt3+), poly [2-(2′-ethyl hexyloxy)-5-methoxy-1,4-phenylenevinylene] (MEH-PPV), poly [5-methoxy-(2-propanoxysulfide)-1,4-phenylenevinylene] (MPS-PPV), poly [2,5-bis-(Hexyloxy)-1,4-phenylene-(1-cyano vinylene)] (CN-PPV), a polyphenylene vinylene (PPV) derivative such as the above, poly (9,9-dioctyl fluorene) (PDAF) and polyspiro. Macromolecule precursor such as PPV precursor and PPP precursor can be used. In addition, existing luminescent material can be used.

Example of a hole transport material comprising a hole transport layer is described below:

copper phthalocyanine, metallophthalocyanine such as tetra(t-butyl) copper phthalocyanine, metal-free phthalocyanine, quinacridon chemical compound, aromatic amine type low molecular hole injection transportation material such as N, N′-di(1-naphthyl)-N, N′-diphenyl-1,1′-biphenyl-4,4′-diamine, 1,1-bis (4-di-p-tolylamino phenyl) cyclohexane, N, N′-diphenyl-N, N′-bis (3-methylphenyl)-1,1′-biphenyl-4,4′-diamine, macromolecule hole transport materials such as polyaniline (PANI), polythiophene, polyvinylcarbazole, mixture with poly (3,4-ethylenedioxy thiophene) (PEDOT) and polystyrene sulfonate, polythiophene oligomer material and other existing hole transport materials.

As an electron transport material used for an electron transport layer, the following material is exemplified:

2-(4-Biphenyl-il)-5-(4-t-butylphenyl)-1,3,4-oxadiazole, 2,5-Bis (1-naphthyl)-1,3,4-oxadiazole, Oxadiazoles, Bis (10-hydroxybenzo [H] quinolinolate) beryllium complex, and triazole compound.

By means of dissolving an organic luminescent material with a solvent, an organic luminescent ink is made. As a solvent, toluene, dimethylbenzene, acetone, hexane, methyl ethyl ketone, methyl isobutyl ketone, cyclohexanone, methanol, ethanol, isopropyl alcohol, ethyl acetate, butyl acetate, 2-carbinyl-(t-butyl) benzene, 1,2,3,4-tetra methylbenzene, pentyl benzene, 1,3,5-triethylbenzene, cyclohexylbenzene and 1,3,5-tri-isopropyl benzene can be used.

The above described material may be used alone. In addition, the above described material can be combined.

Aromatic hydrocarbon is preferable.

In addition, detergent, antioxidant, viscosity modifier and UV absorber may be added in an organic luminescent ink if necessary.

For a solvent in which a hole transport material and an electron transport material dissolve, a toluene, xylene, acetone, methyl ethyl ketone, methyl isobutyl ketone, cyclohexanone, methanol, ethanol, isopropanol, ethyl acetate, butyl acetate, water and the like can be used.

These solvents may be used-alone or in combination.

Water or alcohols are especially preferred to make a ink of a hole transport material.

An organic luminescent layer and a luminescent assist layer are formed by a wet method.

In addition, when the layer sandwiched between electrodes is a laminate, each layer of the laminate is not necessary to be formed by a wet method.

For wet method, the following method can be used: application methods such as a spin coat method, a die coat method, a dip coat method; a discharge coat method, a precoat method, a roll coat method and a bar coat method, and printing methods such as relief printing, ink jet process, offset printing and photogravure process.

When a pattern-shaped organic luminescent layer of three colors of RGB is formed, it can be formed selectively on picture element regions by a printing method. Therefore, an organic electroluminescence element of full colors can be manufactured. The film thickness is lower than 1,000 nm whether the organic luminescence medium layer is monolayer or a laminate. Preferably it is 50 nm-150 nm.

An organic luminescent layer of the present invention is formed by relief printing.

In an ink jet printing, ink is discharged towards a substrate from a discharge jet which is an ink feeding body. There is spacing between a discharge jet and a substrate. Ink discharged to a substrate is scattered by its bouncing at a substrate.

On the other hand, in relief printing, an ink transfers in the condition that a plate, which is an ink supply element contacts a substrate. Therefore, an ink is not scattered. So a predetermined ink can be applied to a prescribed position.

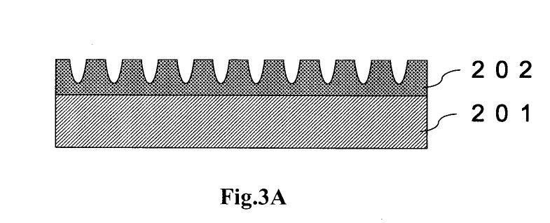

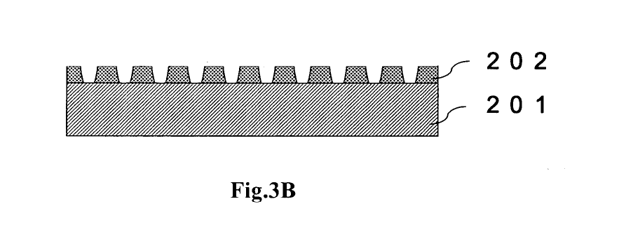

An illustration sectional drawing of a plastic plate of the present invention is shown in FIGS. 3A and 3B.

A plastic plate of the present invention comprises a projection pattern comprising a resin on a metal base. A metal relief printing plate of the present invention that projection pattern 202 comprising resin is formed on metal base 201 is shown in FIG. 3A. According to the present invention, a metal base is used as a base material. So, as compared to case of a base material of a plastic film, dimensional change of a plastic plate in presswork can be controlled.

In addition, as for a metal relief printing plate of the present invention, each projection pattern comprising resin may be formed indepently of an adjacent projection pattern shown in FIG. 3B. In this case, for dimensional change due to a resin, only dimensional change in projection pattern should be considered. It is not necessary to consider dimensional change of the whole plate due to a resin. Therefore, dimensional change of a plastic plate over time can be further controlled.

A base material comprising a plastic plate used for the present invention should have the following characteristics:

1. The rigidity that is enough to control dimensional change of a resin portion.

2. Dimensional change of a base material itself is low.

Because a main component of a resin plate used for the present invention is a hydrophilic polymer, it is easy to absorb moisture. Therefore, dimensional change of a resin plate due to the absorption of moisture or the drying is easy to occur. Dimensional change of a resin layer can be controlled by a rigid base material in order to control the above mentioned dimensional change as much as possible. As for a base material itself, dimensional change due to moisture should not occur at all. For a base material satisfying such requirements, a metal base material is desirable. A steel base material and an aluminum base material are preferred from the viewpoints of workability and cost.

Even more particularly, as factor of dimensional change of a plastic plate, dimensional change due to temperature change is considered. However, if dimensional change due to temperature change of a base material itself is low, dimensional change as a plastic plate can be controlled. Therefore, a base material of which coefficient of thermal expansion is small is desirable for a base material. It is preferable for coefficient of thermal expansion of a metallic material used for a base material to be equal to or less than 2.0*10⁻⁵/K. More preferably, it is equal to or less than 3.0*10⁻⁶/K. Coefficient of thermal expansion of a metal such as ferrum is much lower than coefficient of thermal expansion of a polyester film (more than 1.00*10⁻⁴/K). From this viewpoint, a metal such as ferrum is suitable as a base material of a plastic plate of the present invention. Ferric coefficient of thermal expansion is 1.21*10⁻⁵/K. Even more particularly, thermal expansion coefficient of Fe—Ni alloy is lower than ferric thermal expansion coefficient. Above all, thermal expansion coefficient of alloy of iron 64% and nickel 36% is lower than 1/10 of thermal expansion coefficient of iron or general metal. Therefore, alloy of iron 64% and nickel 36% is the most preferred alloy.

In addition, a plastic plate in the present invention is wound around a cylinder, and it is used. Therefore, it is required that a plastic plate has flexible characteristics. Therefore, a metal plate is as thin as possible when a metal plate is used as a base material. When iron or an alloy of iron and nickel are used, the thickness should be 0.1-0.2 mm.

A resin for projection pattern of a plastic plate in the present invention should have organic luminescence ink solvent resistance.

For example, the following materials can be used: rubber such as a butadiene acrylonitrile rubber, a silicone rubber, an isoprene rubber, styrene-butadiene rubber, butadiene rubber, chloroprene rubber, an isobutylene-isoprene rubber, an acrylonitrile rubber, an ethylene propylene rubber, urethane rubber; synthetic resin such as polyethylen, polystyrene, polybutadiene, polyvinylidene chloride, polyamide, polyethersulfone, polyethylene terephthalate, polyethylenenaphthalate, polyethersulfone and polyvinyl alcohol; copolymer thereof natural polymers such as cellulose; and fluorinated resin such as fluorine system elastomer, polytetrafluoroethylene, polyvinylidene fluoride, poly 6 vinylidene fluoride or copolymer thereof. One or more kind of material among the above mentioned materials can be chosen.

In addition, a water-developable light-sensitive resin is preferred when photo-lithography method is used as formation method of projection pattern comprising resin. A water-developable light-sensitive resin has high resistance to a organic solvent. A well-known material can be used for a water-developable light-sensitive resin. For example, the type of which components are hydrophilic polymer, unsaturated bond-containing monomer and photoinitiator is illustrated. In this type, polyamide, polyvinyl alcohol and cellulosic can be used as a hydrophilic polymer. In addition, for example, methacrylate having a vinyl bonding can be used for unsaturated bond-containing monomer. For example, an aromatic carbonyl compound can be used for photoinitiator. Above all, a water-developable light-sensitive resin of polyamide system is suitable from the viewpoint of printability.

A manufacturing method of a plastic plate of the present invention is shown.

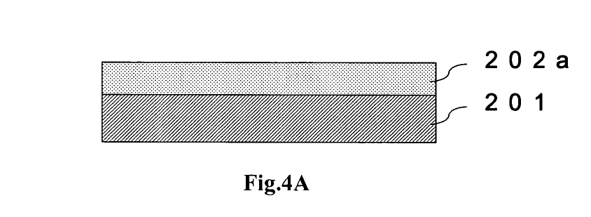

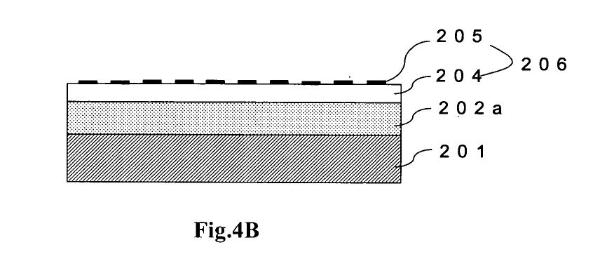

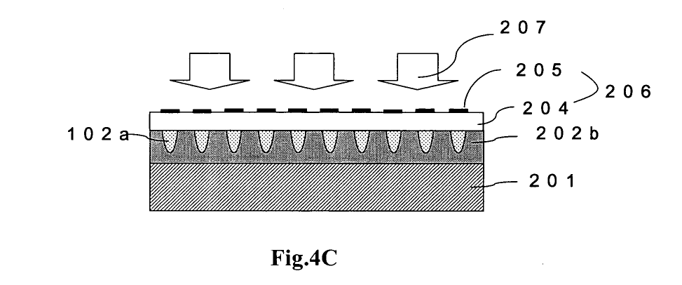

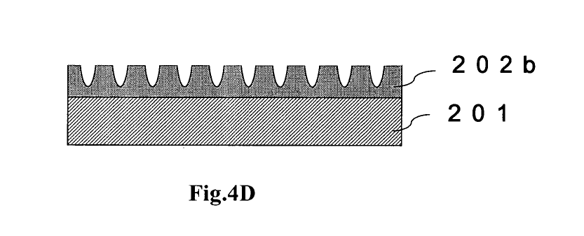

A light-sensitive resin is used as a resin. Projection part is formed by photo-lithography method. Illustration sectional drawing of a manufacturing method of a plastic plate is shown in FIGS. 4A, 4B, 4C and 4D.

At first, a plate that a light-sensitive resin 202a is formed on all over a metal base material 201 is prepared. (FIG. 4A)

Next, photo mask 206 which have light shielding parts and light transmissive parts and which a pattern is formed by light transmissive parts is placed on a light-sensitive resin (FIG. 4B). For example, as for the photo mask, pattern of light shielding part 205 comprising chromium film is formed on translucent glass 204. The part where chromium film is formed is a light shielding part. The part where chromium film is not formed is a light transmissive part.

Next, active energy ray 207 represented by ultraviolet light is irradiated to a resin through the photo mask (FIG. 4C).

Then, a part is hardened by irradiation of the active energy ray which has passed the light transmissive part of the photo mask.

Next, a photo mask is taken off a plastic plate. And developing is performed. A non-hardened zone 102a is removed by developing. In this way, a plastic plate of the present invention shown in FIG. 4D is formed. A non-hardened zone dissolves by water, in case with the use of a plastic plate of water developable type, water is employed as a liquid developer. In addition, after developing, a bake and re-exposure may be performed for the purpose of further curing the resin layer.

In addition, as formation method of projection pattern 202b of a plastic plate, laser ablation method and cutting work can be used, too.

Relief printing with the use of a plastic plate in the present invention is explained next.

A relief printing apparatus of a method to print on a flat plate is available for a relief printing apparatus used for formation of an organic luminescent layer.

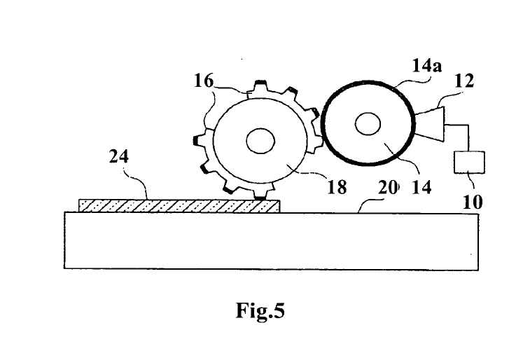

The following printer is desirable. A schematic diagram of a relief printing apparatus used in the present invention is shown in FIG. 5. This manufacturing apparatus has ink tank 10, ink chamber 12, anilox roll 14 and plate cylinder 18 which plastic plate 16 is attached to. An organic luminescent ink diluted with a solvent is accommodated in ink tank 10. An organic luminescent ink is sent into ink chamber 12 from ink tank 10. Anilox roll 14 rotates close against an ink supply of ink chamber 12 and plate cylinder 18.

Organic luminescent ink 14a supplied from ink chamber is held uniformly on anilox roll surface by rotation of anilox roll 14. Then, the organic luminescent ink on anilox roll surface is transferred with uniformity on a convex part of plastic plate attached on a plate cylinder. A substrate 24 is fixed on a substrate fixing stage 20 which is slidable. While a positioning mechanism between a printing plate pattern and a substrate pattern is positioning a substrate, a substrate is moved to a printing staring point. Even more particularly, while a convex part of a plastic plate is close against a substrate, a plastic plate moves in correspondence with rotation of a plate cylinder. Pattern-shaped ink is transferred in predetermined position of a substrate.

A second electrode is formed next.

When a second electrode is a cathode, a material with high electron injection efficiency can be used.

By way of example, metal simple substances such as Mg, Al and Yb are used as the second electrode.

In addition, the following layer stack may be put in a boundary surface of the luminescent medium. The layer stack consists of chemical compound of about 1 nm thicknesses such as Li and oxidation Li, LiF, and Al and Cu which is stable and highly conductive.

On the other hand, stability should be balanced with electron injection efficiency. Therefore the following alloy system may be used: Alloy of one or more kind of metals such as Li, Mg, Ca, Sr, La, Ce, Er, Eu, Sc, Y and Yb of which work function is low, and metallic element such as Ag, Al and Cu which are stable. By way of example, alloy such as MgAg, AlLi and CuLi can be used.

It is desirable to select a material having translucency in so-called top emission construction that visible radiation comes out of the second electrode side.

By way of example, rarefaction by assembly of these metals and clear electrically conducting layer such as ITO can be employed.

As a formation method of a second electrode, dry process method such as resistance heating evaporation method, electron-beam evaporation technique, reactivity evaporation method, ion plating method and sputtering method can be used depending on the material. In addition, patterning can be done by using a mask when patterning of a second electrode is necessary. As for the thickness of a second electrode, 10 nm-1,000 nm are preferable.

In addition, a first electrode may be a cathode in the present invention. A second electrode may be a anode.

As an organic electroluminescent element, an organic luminous layer is sandwiched between electrodes, and it can emit light by applied electric current. However, an organic luminous layer, a luminous assist layer and electrodes deteriorate easily by means of atmospheric moisture and oxygen. Thus a seal to intercept an organic luminous layer and the like from the outside is usually provided.

In addition, a glass cap and a metal cap having a concavity are used, and an organic electroluminescent element can be sealed. A top face of a second electrode corresponds to the concavity. About the penumbra, the cap and the substrate are adhered.

A sealing body is explained below.

By way of example only, a substrate that a first electrode, an organic luminescent layer and a second electrode are formed is prepared. A resin layer is provided over a sealing medium. A sealing medium is stuck on a substrate by means of a resin layer.

For a sealing medium, it is necessary for transmissivity of moisture and oxygen to be low.

In addition, as an example of a material for a sealing medium, ceramics such as alumina, silicon nitride, boron nitride, glass such as no-alkali glass, alkali glass, quartz, metallic foil such as aluminium or stainless, humidity resistance film are exemplified.

By way of example, the following humidity resistance film is exemplified:

A film which is formed SiOx by CVD method on both sides of a plastic substrate; a film which laminated the film that transmissivity of moisture and oxygen is small and hydrophilic film; and a film which water absorption agent was applied on the film that transmissivity of moisture and oxygen is small.

It is preferable for water vapor permeation rate of the humidity resistance film to be less than 10⁻⁶ g/m²/day.

For example, for a resin layer, the following material can be used:

A photo-curing adhesive property resin, a heat curing adhesive property resin, 2 fluid hardening adhesive property resins comprising an epoxy type resin, acrylic resin, silicone oil and the like, acrylic resin such as ethylene ethylacrylate (EEA) polymer, vinyl resins such as ethylene vinyl acetate (EVA), thermoplastic resin such as polyamide, a synthetic rubber, thermoplasticity adhesive property resins such as acid denatured substances of polyethylen or polypropylene.

An example of method to form a resin layer on a sealing medium is shown below: solvent solution method, pushing out laminate method, fusion/hot melt method, calender method, discharge jet application method, screen printing, vacuum laminate method and heated roll laminate method.

A material having hygroscopicity and a property to absorb oxygen can be incorporated into a resin layer if necessary.

Depending on size and configuration of a sealed organic electroluminescent display unit, thickness of a resin layer formed on a sealing medium is fixed. As for the thickness of a resin layer, about 5-500 μm are desirable.

In a sealing room, a substrate with a first electrode, an organic luminous layer, an organic luminous assist layer and a second electrode is affixed to a sealing body.

When it is two layers construction consisting of a sealing medium and a resin layer of thermoplastic resin, contact bonding should be performed only by heating roller.

In the case of a heat curing type adhesion resin, it attaches by pressure by heating roller. And a heat curing type adhesion resin is heated, and is hardened.

At first, in the case of a photo-curing-related adhesion resin, it is sealed by pressure by roller. And a photo-curing-related adhesion resin is stiffened by irradiating a light.

In addition, in the above described example, a resin layer is formed on a sealing medium. However, after having formed a resin layer on a substrate, it may be stuck with a sealing medium.

Before sealing by means of a sealing body, inorganic thin film may be formed. By way of example only, as a passivation film, a silicon-nitride film of which thickness is 150 nm is formed by CVD method. In addition, a sealing body consisting of an inorganic thin film can be formed.

An organic electroluminescence element manufactured by a manufacturing method of the present invention is manufactured with the use of a plastic plate comprising a metal base material. Therefore, as compared to case with the use of a plastic base material, color mixture luminescence due to positional deviation of a printed organic luminescent layer does not occur. In addition, dimensional change over time is suppressed. In addition, when a panel is made with the use of this organic electroluminescence element and emitting state of this panel is observed, color mixture does not occur.

In a manufacturing method of an organic electroluminescence element of the present invention, the optimum base material having the following characteristic is chosen:

1. Dimensional change of a plastic plate can be controlled as much as possible.

2. Attachment of a plastic plate to a printing cylinder is enabled.

An organic luminescent layer of an electroluminescent element can be formed highly minutely by a printing method with the use of a plastic plate having the above mentioned base material. Even more particularly, if printing is performed under environment such as a clean room where temperature management is performed, because a base material of a metal system is used as base material of a plastic plate, misregister in printing due to dimensional change can be controlled.

In one embodiment, convex part pattern comprising a resin on a metal base material of a plastic plate is formed independently of adjacent convex part pattern. Then, it is not necessary to consider dimensional change of the whole of a plate which convex part pattern is formed. Therefore, dimensional change over time of a plastic plate can be further controlled.

### EXAMPLE 1

A relief printing plate to form an organic luminescent layer was a water-developable plastic plate including a light-sensitive resin layer of polyamide system and a base material of a steel plate of which thickness was 0.2 mm. A plastic plate was formed by UV exposure with the use of a negative mask and developing by water. This plastic plate was attached to the previously described printer, and an organic luminescent layer was printed.

Sputter method was used, and ITO thin film was formed on a glass substrate of 300 mm square. ITO film was patterned by photolithography method and etching by an acid solution. Pixel electrodes for two display units of which a diagonal size was 5 inches were formed.

Line pattern of pixel electrodes for one display unit is described below. The line width was 40 μm. The space was 20 μm. The number of lines was 1950.

As a hole transport layer, a polymer membrane comprising PEDOT was formed on this substrate by a spin coat method.

The following organic luminescence inks of red, green and blue were prepared:

Red luminescence ink (R): The solution which a poly fluorene system derivative dissolves in a toluene. (The density of a poly fluorene system derivative was 1% by weight.) (red luminescence material made in chemical Sumitomo Corporation:commercial name Red1100)

Green emission ink (G): The solution which a poly fluorene system derivative dissolves in a toluene. (The density of a poly fluorene system derivative was 1% by weight.) (green emission material made in chemical Sumitomo Corporation: commercial name Green1300)

Blue luminescence ink (B): The solution which a poly fluorene system derivative dissolves in a toluene. (The density of a poly fluorene system derivative was 1% by weight.) (blue luminescence material made in chemical Sumitomo Corporation: commercial name Blue1100)

An organic luminescent layer corresponding to the first electrode line pattern was formed in an upper part of the first electrode by relief printing. In this case, an anilox roll of 150 line/inch and a water-developable photosensitive resin plate were used. The film thickness of the organic luminescent layer after printing and drying became 80 nm.

Thereupon, cathode layers (second electrodes) comprising Ca, Al was formed by resistance heating evaporation method with the use of a mask in the line pattern which was perpendicular to line pattern of the pixel electrodes.

Finally, a glass cap and adhesive were used, and these electroluminescence members were sealed to protect them from outside oxygen and moisture. An electroluminescence display panel was made in this way.

In a penumbra of displaying part of the obtained panel, there were taking-out electrodes of anode (pixel electrodes, first electrode) side connected to each pixel electrodes and of cathode (second electrode) side.

Lighting/display of a panel was confirmed by connecting these taking-out electrode to a power source. In addition, emitting state was checked.

In addition, about a resin plate used in the present embodiment, dimensional change under constant temperature of 25 degrees Celsius after plate-making was measured with time. Even more particularly, dimensional changes at 20 degrees Celsius and 30 degrees Celsius were measured. The coefficient of thermal expansion of a steel base material used for the present embodiment was 1.21*10⁻⁵/K.

### EXAMPLE 2

The relief printing plate to form an organic luminescent layer was a water-developable plastic plate including a light-sensitive resin layer of polyamide system and a base material comprising a copper sheet of which thickness was 0.2 mm. As for this plastic plate, plate-making was performed by the same method as example 1. A trial manufacture of a panel was performed by the same method as example 1.

In addition, about this plastic plate, dimensional change was measured by the same method as example 1. The coefficient of thermal expansion of a copper base material used in example 2 was about 1.68*10⁻⁵/K.

### EXAMPLE 3

The relief printing plate to form an organic luminescent layer was a water-developable plastic plate including a light-sensitive resin layer of polyamide system and a base material comprising an alloy plate of which thickness was 0.2 mm. This alloy plate was an alloy of iron and nickel. The content of nickel was 36%.

The plate-making of this water-developable plastic plate was performed by the same method as example 1. A trial manufacture of a panel was performed by the same method as example 1.

In addition, about this plastic plate, dimensional change was measured by the same method as example 1. Coefficient of thermal expansion of this alloy base material of iron and nickel was 3*10⁻⁶/K.

### Comparative Example 1

The relief printing plate to form an organic luminescent layer was a water-developable plastic plate including a light-sensitive resin layer of polyamide system and a base material comprising a polyester sheet of which thickness was 0.5 mm.

The plate-making of this plastic plate was performed by the same method as example 1. A trial manufacture of a panel was performed by the same method as example 1.

In addition, about this plastic plate, dimensional change was measured by the same method as example 1. The coefficient of thermal expansion of a polyester base material was about 9.0*10⁻⁵/K.

### Comparative Example 2

The relief printing plate to form an organic luminescent layer was a water-developable plastic plate including a light-sensitive resin layer of polyamide system and a base material comprising aluminium of which thickness was 0.2 mm.

The plate-making of this plastic plate was performed by the same method as example 1. A trial manufacture of a panel was performed by the same method as example 1.

In addition, about this plastic plate, dimensional change was measured by the same method as example 1.

The coefficient of thermal expansion of aluminium base material was about 2.5*10⁻⁵/K.

### Comparative Example 3

The relief printing plate to form an organic luminescent layer was a water-developable plastic plate including a light-sensitive resin layer of polyamide system and a base material comprising steel of which thickness was 0.5 mm.

The plate-making of this plastic plate was performed by the same method as example 1.

The organic luminescent layer was not able to be printed by a plastic plate of comparative example 3.

Result of a measurement of dimensional change of a plastic plate used in example 1-3 and comparative example 1-3 and an estimation result of emitting state of a prepared panel are shown in table 1.

TABLE 1

| | | | estimation item | | |
|---|---|---|---|---|---|
| | | | | Dimensional change | |
| | | | | due to temperature | |
| | Kind of base | Thickness of | Maximum dimensional | change of 5 degrees | Emitting state of a |
| Sample | material | base material(mm) | change over time (μm) | Celsius (μm) | panel (note 1) |
| Example 1 | Steel | 0.2 | 0 | 9 | ∘ |
| Example 2 | Copper | 0.2 | 0 | 12 | ∘ |
| Example 3 | Iron-Nickel | 0.2 | 0 | <1 | ∘ |
| | alloy | | | | |
| Comparative | PET | 0.2 | 60 | 50 | x |
| Example 1 | | | | | |
| Comparative | Al | 0.2 | 0 | 18 | ∘ |
| Example 2 | | | | | |
| Comparative | Steel | 0.5 | 0 | 9 | — |
| Example 3 | | | | | |

Note 1:
Emitting state of a panel
∘: Excellent without Color mixture
x: Bad with Color mixture
—: Non-manufacture of a panel (Printing is impossible)

The dimensional change was measured as previously described. After plate-making, a size of a plastic plate was measured with time under environment of 25 degrees Celsius. Maximum amount of change per one panel in this case was measured. The size of one panel was 117 mm.

After dimensional change reached equilibrium, operation which raised 5 degrees Celsius of environmental temperature was performed. And quantity of dimensional change after 24 hour was measured.

Estimation method of emitting state is described below.

A panel was made to emit light by joining a power source to taking-out electrode of a panel. Existence or nonexistence of color mixture luminescence due to positional deviation of a printed luminescent layer was observed.

60 μm dimensional change per one panel occurred in case of the plastic plate that PET sheet was a base material (comparative example 1). When emitting state of a panel was observed, color mixture in luminescence due to misregister in printing was observed. As for the pixel electrodes (first electrode) line of a panel produced experimentally, width of the line was 40 μm, and width of the space was 20 μm. Therefore, if there was dimensional change of 60 μm per one panel, necessarily misregister in printing occurred.

On the other hand, the dimensional change over time did not occur in case of the plastic plate comprising metal base material like example 1-3 and comparative example 2. In addition, after having formed a panel, emitting state was observed, and the color mixture did not occur.

Therefore, if it is printed using a base material of a metal system in environment such as clean rooms where temperature management is carried out, misregister in printing due to dimensional change does not almost occur.

In addition, when printing in the environment which temperature management can not be carried out is considered, the metallic material of which coefficient of thermal expansion is very small is desirable.

As for the iron-nickel alloy used in example 3, nickel content is 36%. An expansion coefficient of this iron-nickel alloy is near to an expansion coefficient of a glass. Therefore, the dimensional change due to temperature change hardly occurs.

Even more particularly, like comparative example 3, a flexible characteristics of the metal substrate of which thickness is about 0.5 mm is very low. Therefore, winding of the plastic plate to a printing cylinder is difficult. The plastic plate in comparative example 3 could not be attached to a printing cylinder. Therefore, printing was not able to be carried out.

On the other hand, like example 1 to 3 and comparative example 2, the metal substrate of which thickness was about 0.2 mm was easily wound around a plate cylinder.

What is claimed is:

1. A manufacturing method of an organic electroluminescent element including a substrate, a first electrode, an organic luminescent layer and a second electrode,
the method including forming an organic luminescent layer in upside of the first electrode by relief printing with the use of an organic luminescence ink, wherein the ink comprises an organic luminescent material dissolved in an organic solvent, and
wherein a plastic plate having projection patterns comprising a resin on a metal base material is used in the relief printing.

2. The manufacturing method of an organic electroluminescent element according to claim 1,
wherein each projection pattern is formed independently of the adjacent projection pattern.

3. The manufacturing method of an organic electroluminescent element according to claim 1,
wherein the resin for the plastic plate is a water-developable photopolymer.

4. The manufacturing method of an organic electroluminescent element according to claim 1,
wherein a main component of the metal base material is a material selected from the group consisting of iron, aluminium, nickel, copper and a combination thereof.

5. The manufacturing method of an organic electroluminescent element according to claim 1,
wherein the metal base material comprises an alloy of iron and nickel.

6. The manufacturing method of an organic electroluminescent element according to claim 1,
wherein the metal base material is a metal having a coefficient of thermal expansion equal to or less than 2.0*10⁻⁵/K.

7. The manufacturing method of an organic electroluminescent element according to claim 1,
wherein the metal base material is a metal having coefficient of thermal expansion equal to or less than 3*10⁻⁶/K.

8. The manufacturing method of an organic electroluminescent element according to claim 1,
wherein thickness of the metal base material made of iron or an alloy of iron and nickel is 0.1-0.2 mm.

9. An organic electroluminescent element including a substrate, a first electrode, an organic luminescent layer and a second electrode,
wherein the organic luminescent layer is formed by the method according to claim 1.
